(19) United States
(12) Patent Application Publication
(10) Pub. No.: US 2013/0341743 A1
(43) Pub. Date: Dec. 26, 2013

(54) DEVICES INCLUDING TANTALUM ALLOY LAYERS

(71) Applicant: SEAGATE TECHNOLOGY LLC, Cupertino, CA (US)

(72) Inventors: Eric Walter Singleton, Maple Plain, MN (US); Liwen Tan, Eden Prairie, MN (US); Jae-Young Yi, Prior Lake, MN (US)

(73) Assignee: SEAGATE TECHNOLOGY LLC, Cupertino, CA (US)

(21) Appl. No.: 13/755,072

(22) Filed: Jan. 31, 2013

Related U.S. Application Data
(60) Provisional application No. 61/663,721, filed on Jun. 25, 2012.

(51) Int. Cl. H01L 43/02

(52) U.S. Cl. CPC H01L 43/02
USPC 257/421

(57) ABSTRACT

A device that includes a sensor stack, the sensor stack including a reference layer, a free layer and a barrier layer positioned between the reference layer and the free layer; a seed layer; and a cap layer, wherein the sensor stack is positioned between the seed layer and the cap layer, and wherein at least one of the seed layer or the cap layer includes TaX, wherein X is selected from Cr, V, Ti, Zr, Nb, Mo, Hf, W, or a combination thereof.

### PRIORITY

This application claims priority to U.S. Provisional Application No. 61/663,721 entitled “DEVICES INCLUDING TANTALUM ALLOY LAYERS” having docket number 430.17140000 filed on Jun. 25, 2012, the disclosure of which is incorporated herein by reference thereto.

### BACKGROUND

Currently utilized magneto-resistive devices, such as magneto-resistive heads for use in magnetic readers, utilize tantalum (Ta) as seed and cap layers in order to assist in the growth of magnetic layers. The mill rate of Ta can be lower than other materials in the stack leading to problems during the milling and lapping process. Therefore, there is a need for other materials for use in seed and/or cap layers.

### SUMMARY

Disclosed herein is a device that includes a sensor stack, the sensor stack including a reference layer, a free layer and a barrier layer positioned between the reference layer and the free layer; a seed layer; and a cap layer, wherein the sensor stack is positioned between the seed layer and the cap layer, and wherein at least one of the seed layer or the cap layer includes TaX, wherein X is selected from Cr, V, Ti, Zr, Nb, Mo, Hf, W, or a combination thereof

Also disclosed herein are magneto-resistive devices that include a bottom shield; a seed layer positioned adjacent the bottom shield; a sensor stack positioned adjacent the seed layer, the sensor stack including a reference layer, a free layer and a barrier layer positioned between the reference layer and the free layer; a cap layer positioned adjacent the sensor stack; and a top shield positioned adjacent the cap layer, wherein at least one of the seed layer or the cap layer includes TaX, wherein X is selected from Cr, V, Ti, Zr, Nb, Mo, Hf, W, or a combination thereof.

These and various other features will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 provides a side view of an embodiment of a tunneling magneto-resistive sensor, in accordance with the present disclosure.

FIG. 2 shows the tunneling magneto-resistive (TMR) effect versus the minimum resistance for a magnetic stack having tantalum as a seed and cap layer and tantalum chromium as a seed and cap layer.

FIG. 3 shows the mill rate of various materials as a function of the mill angle.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

“Include,” “including,” or like terms means encompassing but not limited to, that is, including and not exclusive.

The present disclosure relates to magnetic stacks that include seed layers, cap layers, or both that are made of tantalum alloys. Such magnetic stacks can be utilized in or as tunneling magneto-resistive (TMR) sensors.

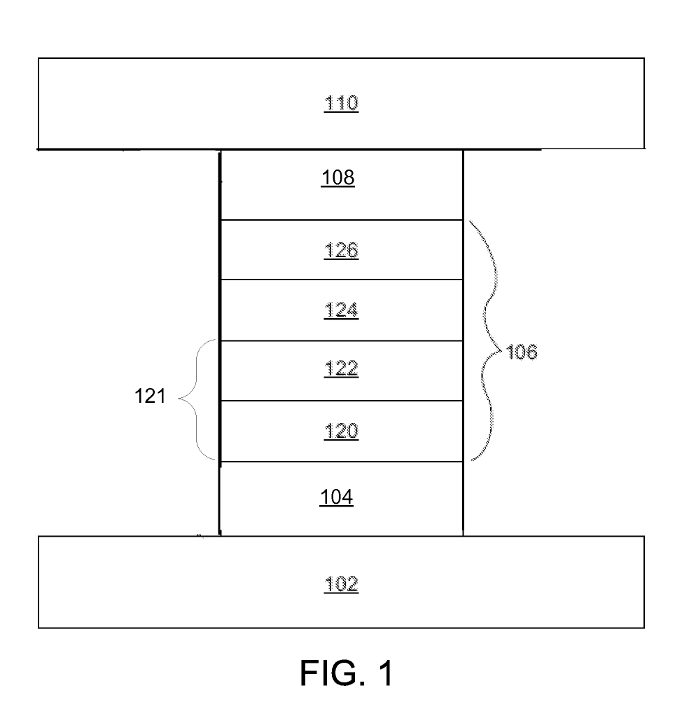

FIG. 1 provides an embodiment of a magnetic device 100 (which can also be referred to as a stack, a magnetic stack or a magneto-resistive device) which can be utilized as a tunneling magneto-resistive (TMR) sensor. This magnetic device 100 can include a bottom shield 102, a seed layer 104, a sensor stack 106, a cap layer 108, and a top shield 110. The sensor stack 106 can include, but is not limited to, a pinning layer 120, a pinned layer 122 (in such an embodiment, the pinning layer 120 and the pinned layer 122 form the reference layer 121), a barrier layer 124, and a free layer 126. Additional and optional layers, such as spacing and insulating layers can also be included in some embodiments of disclosed magnetic devices.

The sensor stack 106 is generally made of various magnetic and non-magnetic materials.

For example, the free layer 126 can generally be a ferromagnetic material. Specific ferromagnetic materials that can be used can include, for example CoFe, CoFeB and NiFe. The barrier or spacer layer 124 is generally an insulating material. Specific insulating materials that can be used can include, for example MgO, Al₂O₃, Y₂O₃, CeO₂, TaO, SiN, AN, CrO₂, HfO₂, ZrO₂ and TiO₂. In instances in which the sensor is to be a TMR sensor, this layer is a barrier layer and in other instances, it is a spacer layer. The pinned layer 122 is generally a ferromagnetic material. Specific ferromagnetic materials that can be used can include, for example CoFe and CoFeB. The pinning layer 120 is generally an antiferromagnetic material. Specific antiferromagnetic materials that can be used can include, for example PtMn, IrMn, NiMn and FeMn. It should also be noted that the sensor stack 106 can be configured to be something other than a tunneling magneto resistance (TMR) sensor. For example, the sensor stack 106 could be configured so that it functions as a giant magneto resistant (GMR) sensor, for example a current perpendicular to plane (CPP) sensor.

During manufacturing and processing of such disclosed magnetic devices, stacks including at least some of the disclosed structures can be subjected to ion milling steps. In magnetic devices that do not utilize tantalum alloys as a seed layer, cap layer, or both, differences in the rate of milling between the materials of the sensor stack and the seed/cap layers can result in magnetic devices that have issues. For example, if the seed and/or cap layers are made of materials that have much lower mill rates than the materials of the sensor stack, longer side mills must be utilized, which can introduce damage to the sensor stack as a thicker, magnetic or electrically dead layer. As requirements for areal density increase, shield to shield spacing (SSS) and reader width (RW) have to be scaled down; issues caused by differences in mill rates could make it difficult if not impossible to scale these dimensions down.

Disclosed herein therefore are magnetic devices that include seed layers, cap layers, or both that are made of tantalum alloys. In some embodiments, the seed layers, cap layers, or both can be a single layer. In some embodiments, the seed layers, cap layers, or both, are not bi-layer structures that include a second layer designed to orient the crystal structure of layers built thereon. In some embodiments, the seed layers, cap layers, or both, are not bi-layer structures that include a second layer made of a non-magnetic nickel alloy. In some embodiments, disclosed seed layers, cap layers, or both can however be utilized in combination with other layers. For example other layers of electrically conducting material, such as ruthenium (Ru). For example, a disclosed see layer, cap layer or both can be utilized adjacent to a layer of Ru (or other material).

In some embodiments, the tantalum alloys can be amorphous. Amorphous layers may enhance the growth of layers that may be formed thereon. Specific tantalum alloys that can be used can include, for example, TaX, where X can be Cr, V, Ti, Zr, Nb, Mo, Hf, W, or combinations thereof. In some embodiments, tantalum alloys can include, for example TaX, where X can be V, Ti, Zr, Nb, Mo, Hf, W, or combinations thereof. In some embodiments, a specific tantalum alloy can include TaCr.

The amounts of the various components (two elements in a binary alloy or three elements in a ternary alloy) can vary. The amount of the elements in an alloy can be chosen, at least in part, based on the desired structure of the alloy (the amounts of the elements can play a role in determining whether the alloy is amorphous, crystalline, or some combination thereof), the effect of the alloy on the magnetic properties of the device, physical properties of the alloy (hardness, etc.), other factors not discussed herein, or combinations thereof

In some embodiments, the amount of Ta in TaX, where X can represent one or more than one elements, can range from 20 atomic % (at %) to 99 at %. In some embodiments, the amount of Ta in TaX, where X can represent one or more than one elements, can range from 40 at % to 80 at %. In some embodiments, the amount of Ta in TaX, where X can represent one or more than one elements, can range from 50 at % to 70 at %. In some embodiments, the amount of X in TaX, where X can represent one or more than one elements, can range from 1 at % to 80 at %. In some embodiments, the amount of X in TaX, where X can represent one or more than one elements, can range from 20 at % to 60 at %. In some embodiments, the amount of X in TaX, where X can represent one or more than one elements, can range from 30 at % to 50 at %. In some embodiments, the amount of X in TaX, where X is Cr, can range from 1 at % to 80 at %. In some embodiments, the amount of X in TaX, where X is Cr, can range from 20 at % to 60 at %. In some embodiments, the amount of X in TaX, where X is Cr, can range from 30 at % to 50 at %.

In some embodiments, only one of the seed layer or cap layer is made of a tantalum alloy.

In some embodiments, both the seed layer and the cap layer are made of a tantalum alloy. In some embodiments, both the seed layer and the cap layer are made of a tantalum alloy, and the tantalum alloy in the seed layer and the cap layer are the same. In some embodiments, both the seed layer and the cap layer are made of a tantalum alloy, and the tantalum alloy in the seed layer and the cap layer are different, either in the identity of the components, the amount of the components, or a combination thereof. The materials to be used in the seed layer, the cap layer, or both can be chosen at least in part, based on their mill rates and the final configuration of the desired structure.

The present disclosure is illustrated by the following examples. It is to be understood that the particular examples, materials, amounts, and procedures are to be interpreted broadly in accordance with the scope and spirit of the disclosure as set forth herein.

### EXAMPLES

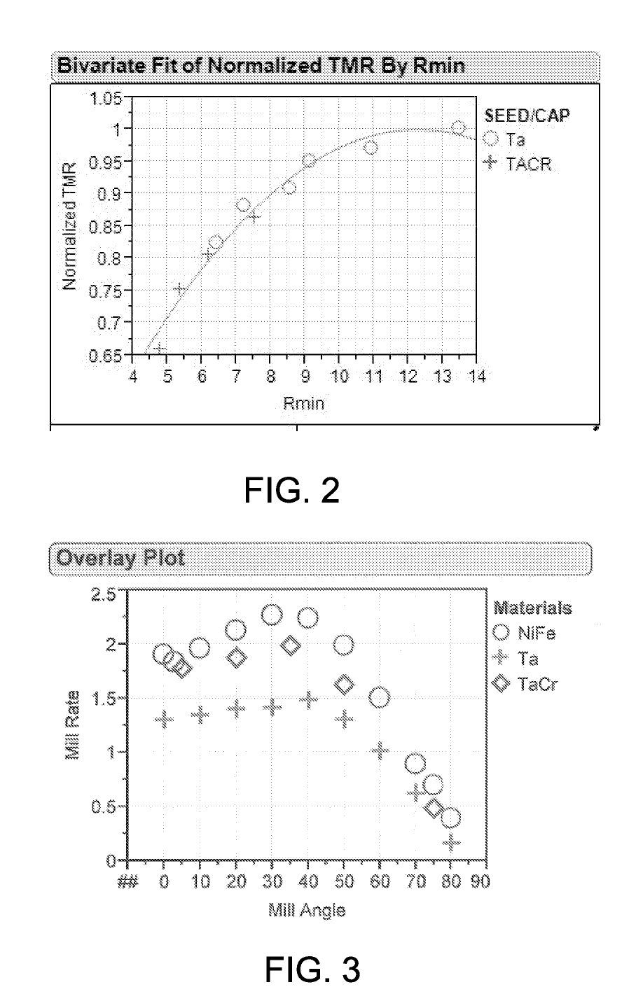

Magnetic stacks similar to that disclosed in FIG. 1 were formed. The first stack utilized tantalum (Ta) as the seed layer and the cap layer. The second stack utilized a tantalum chromium (TaCr) alloy having 40 at % of Cr. FIG. 2 shows the tunneling magneto-resistive (TMR) effect versus the minimum resistance (RMIN) of the two stacks. As seen there, the stack that included TaCr performed as well as the stack that utilized Ta, in that the TMR was not degraded.

FIG. 3 shows the mill rate of various materials (NiFe, Ta, and TaCr-40 at % Cr) as a function of the mill angle. As seen there, TaCr has a much higher mill rate than Ta (about 40% higher), and is quite close to the mill rate of NiFe.

Thus, embodiments of devices including tantalum alloy layers are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation.

What is claimed is:

1. A device comprising:
a sensor stack, the sensor stack comprising a reference layer, a free layer and a barrier layer positioned between the reference layer and the free layer;
a seed layer; and
a cap layer,
wherein the sensor stack is positioned between the seed layer and the cap layer, and wherein at least one of the seed layer or the cap layer comprises TaX, wherein X is selected from Cr, V, Ti, Zr, Nb, Mo, Hf, W, or a combination thereof.

2. The device according to claim 1, wherein the seed layer and the cap layer are amorphous.

3. The device according to claim 1, wherein the seed layer comprises TaX, wherein X is selected from Cr, V, Ti, Zr, Nb, Mo, Hf, W, or a combination thereof.

4. The device according to claim 1, wherein the cap layer comprises TaX, wherein X is selected from Cr, V, Ti, Zr, Nb, Mo, Hf, W, or a combination thereof.

5. The device according to claim 1, wherein both the seed layer and the cap layer independently comprise TaX, wherein X is selected from Cr, V, Ti, Zr, Nb, Mo, Hf, W, or a combination thereof

6. The device according to claim 1, wherein at least one of the seed layer or the cap layer comprises TaCr.

7. The device according to claim 6, wherein the atomic percent of Cr in the TaCr is from about 1% to about 80%.

8. The device according to claim 6, wherein the atomic percent of Cr in the TaCr is from about 20% to about 60%.

9. The device according to claim 6, wherein the atomic percent of Cr in the TaCr is from about 30% to about 50%.

10. A magneto-resistive device comprising:
a bottom shield;
a seed layer positioned adjacent the bottom shield;
a sensor stack positioned adjacent the seed layer, the sensor stack comprising a reference layer, a free layer and a barrier layer positioned between the reference layer and the free layer;
a cap layer positioned adjacent the sensor stack; and
a top shield positioned adjacent the cap layer,
wherein at least one of the seed layer or the cap layer comprises TaX, wherein X is selected from Cr, V, Ti, Zr, Nb, Mo, Hf, W, or a combination thereof.

11. The magneto-resistive device according to claim 10, wherein the seed layer and the cap layer are amorphous.

12. The magneto-resistive device according to claim 10, wherein the seed layer comprises TaX, wherein X is selected from Cr, V, Ti, Zr, Nb, Mo, Hf, W, or a combination thereof.

13. The magneto-resistive device according to claim 10, wherein the cap layer comprises TaX, wherein X is selected from Cr, V, Ti, Zr, Nb, Mo, Hf, W, or a combination thereof.

14. The magneto-resistive device according to claim 10, wherein both the seed layer and the cap layer independently comprise TaX, wherein X is selected from Cr, V, Ti, Zr, Nb, Mo, Hf, W, or a combination thereof .

15. The magneto-resistive device according to claim 10, wherein at least one of the seed layer or the cap layer comprises TaCr.

16. The magneto-resistive device according to claim 15, wherein the atomic percent of Cr in the TaCr is from about 20% to about 60%.

17. The magneto-resistive device according to claim 15, wherein the atomic percent of Cr in the TaCr is from about 30% to about 50%.
